(19) United States
(12) Patent Application Publication
(10) Pub. No.: US 2003/0124831 A1
(43) Pub. Date: Jul. 3, 2003

(54) Method of forming a bump

(76) Inventors: Chung-Liang Hsiao, Taipei (TW); Chien-Hsin Ko, Hsinchu (TW)

Correspondence Address: J.C. Patents, Inc., Suite 250, 4 Venture, Irvine, CA, 92618, US

(21) Appl. No.: 10/034,876

(22) Filed: Dec. 27, 2001

(51) Int. Cl. H01L 21/44

(52) U.S. Cl. 438/613

(57) ABSTRACT

A method of forming a bump includes performing wet etching a bonding pad on the wafer, and then sequentially forming an under ball metallurgy layer and a bump. Hillocks on the bonding pad can be removed after the wet etching process, and the bump has a planar or concave surface, whereby no nodules are formed on the bump.

### BACKGROUND OF THE INVENTION

1. Field of the Invention

The present invention relates to a method of forming a bump. More specifically, the present invention relates to a method of forming a bump, where no nodule is formed on the bump.

2. Description of the Related Art

With the rapid progress in liquid crystal display technology has come a new generation of the liquid crystal display devices having characteristics such as higher brightness, broader view angle range, higher response speed, higher image resolution and full color. However, these characteristics are affected by various factors such as the orientation of liquid crystal molecules, the properties of the pixel electrode, the type of color filter, the manufacture process of forming the film transistor, the materials of an alignment layer and a sealant, and packaging etc. In order to have a liquid crystal display device with high image resolution, light weight and compactness, the packaging technology has developed from chip-on-board (COB), to a tape automated bonding (TAB), into a fine pitch chip-on-glass (COG) technology.

Chip-on-glass (COG) technology is commonly used to electrically connect a driver chip to a liquid crystal display panel by means of an anisotropic conductive film. The anisotropic conductive film is provided on the driver chip region of the liquid crystal display panel. The driver chip is located on the anisotropic conductive film by flip chip technology. The conductor bump on the driver chip is electrically connected to the liquid crystal display panel via conductive particles in the anisotropic conductive film. Because the driver chip drives the liquid crystal display panel, the bonding reliability of the conductor bump with the liquid crystal display panel is critical.

FIG. 1 is a flow chart showing a method of forming a conductor bump in the prior art. A conventional method of forming a conductor bump includes steps of providing a wafer 100, performing a dry etching process 102, forming an under ball metallurgy (UBM) layer 104, and forming a conductor bump 106. Because the bonding pad uncovered by a protection layer is exposed to the atmosphere, a native oxide layer may be formed on the exposed bonding pad. A dry etching process is performed to remove the native oxide layer (102). After the native oxide layer is removed, the UBM layer is formed 104. A conductor bump is formed on the UBM layer (106).

FIG. 2 is a schematic, cross sectional view of a conductor bump formed by a conventional method. A wafer 200 having a plurality of bonding pads 202 is provided. The wafer 200 also has a protection layer 206 that protects the wafer 200 and exposes the bonding pad 202 for external connection. Normally, on the bonding pad 202, hillocks exist having sizes of about 0.2 micron to about 0.3 micron. The bonding pad 202 is further provided with a UBM layer 208 thereon. A bump 210 is formed on the UBM layer 208. The hillocks 204 on the bonding pad 202 adversely affect the formation of a bump 210 having a planar surface. Specifically, because of the hillocks 204 on the bonding pad 202, the portion of the bump formed directly on the hillock protrudes and forms a nodule which makes the surface of the bump uneven.

Electric connection between a liquid crystal display panel and a driver chip thereon can be achieved by an anisotropic conductive film (ACF). Bumps on the driver chip are electrically connected to the liquid crystal display panel by pressing conductive particles in an anisotropic conductive paste. If any nodule exists on the bump of the driver chip, the reliability with respect to electric connection between the driver chip and the liquid crystal display panel will be deteriorated.

Because of the nodules on the bump caused by the hillocks on the bonding pad, an uneven bump surface is inevitably formed. In order to improve the electric connection between the driver chip and the liquid crystal display panel, one approach is to limit the ratio of the area of the nodule relative to the area of the bump to be less than 10%, and control the height of the nodule to be less than 2 micron.

### SUMMARY OF THE INVENTION

One object of the present invention is to provide a method of forming a conductor bump on which no nodule is formed.

In order to achieve the above and other objects of the present invention, a method of forming a bump is provided, in which a bonding pad on the wafer is pretreated by wet etching. Hillocks, which are formed on the bonding pad in a common process, can be removed after wet etching, and the bonding pad, therefore, can have a substantially planar or concave surface. Then, an under ball metallurgy (UBM) layer and a bump are sequentially formed. After wet etching, the bonding pad has a planar or concave surface that prevents nodules from being formed on the bump in the subsequent process. Since the bump has no nodules, it can provide high reliability in processes that require high planarity of the bump.

Before the UBM layer is formed, the bonding pad is subjected to a dry etching process to remove native oxide, if any, on the bonding pad, to increase the bondability of the bonding pad to the UBM layer.

The bonding pad can be made of aluminum, for example. Etchant used in the wet etching process can be selected from hydrogen fluoride, peroxide such as hydrogen peroxide, and acids such as 60%-80% phosphoric acid (H₃PO₄), more than 10% nitric acid (HNO₃), more than 10% acetic acid (CH₃COOH) or the combination thereof.

### BRIEF DESCRIPTION OF THE DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 is a flow chart showing a method of forming a bump in the prior art;

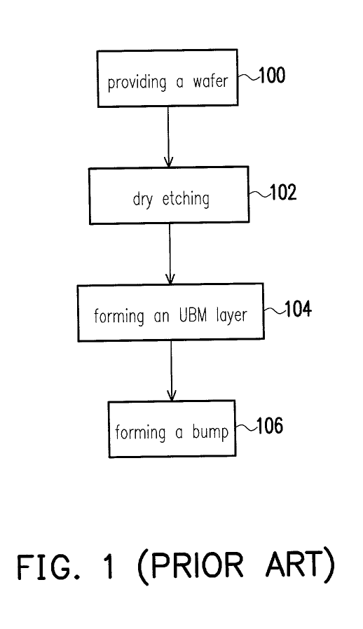

FIG. 2 is a schematic, cross sectional view of a bump formed by a conventional method of forming the bump;

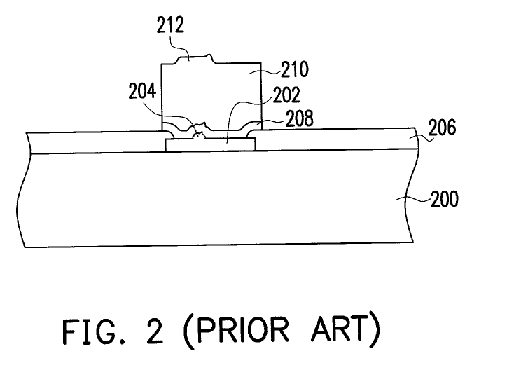

FIG. 3 is a flow chart showing a method of forming a bump according to a preferred embodiment of the present invention;

FIG. 4 is an SEM chart showing a bonding pad before a wet etching according to a preferred embodiment of the present invention;

FIG. 5 is an SEM chart showing a bonding pad after a wet etching according to a preferred embodiment of the present invention; and

FIG. 6 is a schematic, cross sectional view of a bump formed according to a preferred embodiment of the present invention.

### DESCRIPTION OF THE PREFERRED EMBODIMENT

Reference will now be made in detail to the present preferred embodiments of the invention, examples of which are illustrated in the accompanying drawings. Whenever possible, the same reference numbers are used in the drawings and the description to refer to the same or like parts.

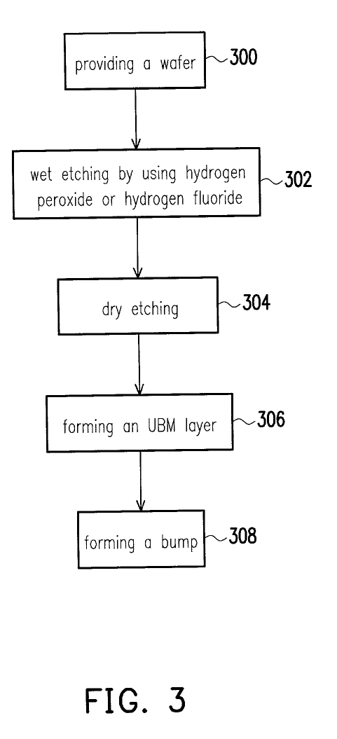

FIG. 3 is a flow chart showing a method of forming a bump according to a preferred embodiment of the present invention. The method of the present invention includes steps of providing a wafer 300, wet etching by using hydrogen peroxide or hydrogen fluoride 302, dry etching 304, forming an under ball metallurgy (UBM) layer 306, and forming a bump 308. A bonding pad is formed on the wafer, usually with a hillock on the bonding pad. In one preferred embodiment of the present invention, the bonding pad is subject to a wet etching 302 using hydrogen peroxide or hydrogen fluoride to remove the hillock on the bonding pad.

Usually, a native oxide layer is formed on the bonding pad due to exposure of the unprotected bonding pad to atmosphere. Therefore, after the wafer is provided 300, a dry etching process 304 is required to remove the native oxide layer on the bonding pad. After removal of the native oxide layer, a UBM layer is formed 306 and then a bump is formed 308. Forming the bump can be achieved by plating, for example.

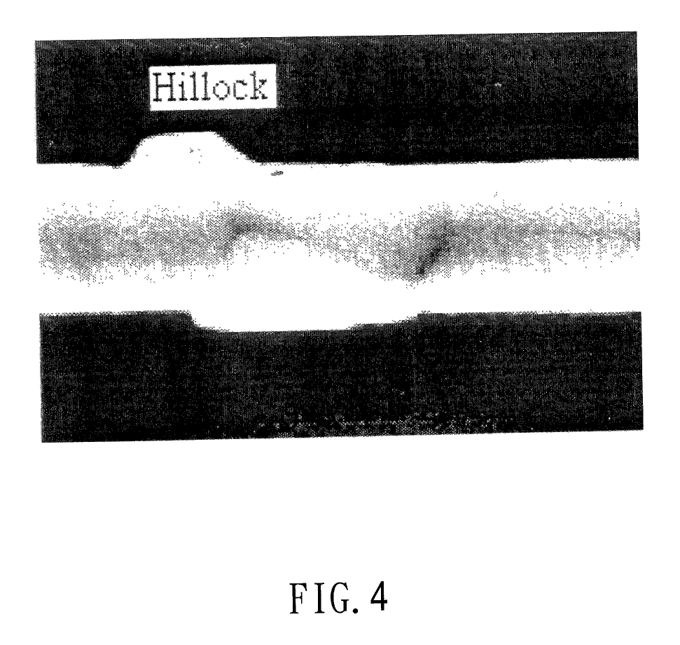

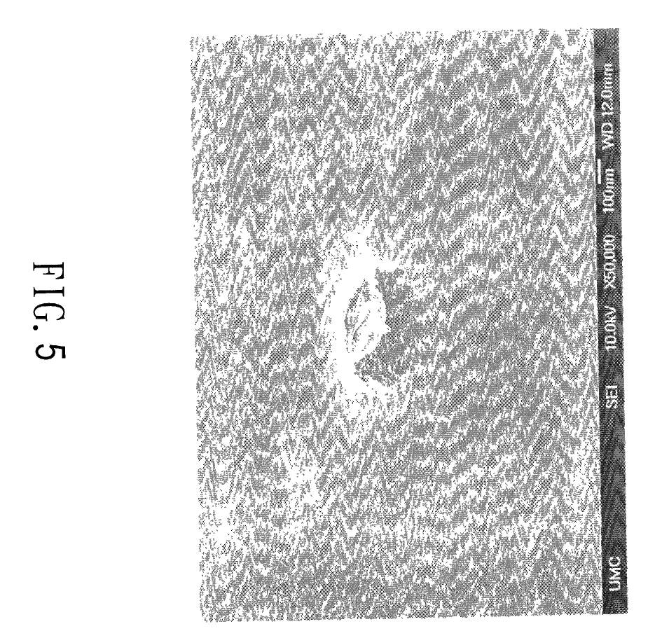

FIGS. 4 and 5 are SEM charts showing a bonding pad before and after a wet etching, respectively, according to a preferred embodiment of the present invention. Many hillocks may be formed on the bonding pad before wet etching, as shown in FIG. 4. These hillocks on the bonding pad cause nodules on the bump after the UBM layer and the bump are sequentially formed. In the present invention, the hillocks on the bonding pad are removed by wet etching to form a smooth or concave topograghy on the top of the bonding pad, as shown in FIG. 5. In the case where the bonding pad has a concave surface after wet etching, the UBM layer and the bump sequentially formed on the bonding pad can compensate for the uneven profile of the bonding pad.

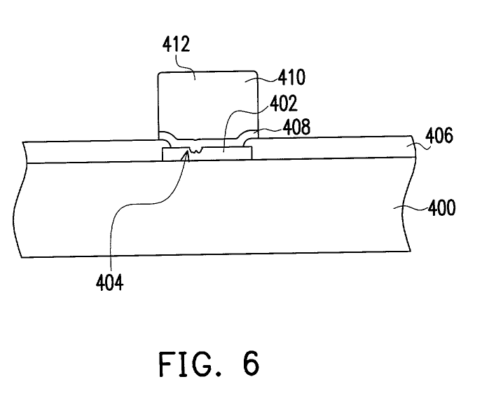

FIG. 6 is a schematic, cross sectional view of a bump formed according to a preferred embodiment of the present invention. The wafer 400 has a plurality of bonding pads 402 and a protection layer 406. The protection layer 406 is used to protect the surface of the wafer 400 and exposes part of the bonding pad 402 for external connection. The bonding pad 402 can be made of metals, such as aluminum. The aluminum bonding pad 402 usually has some hillocks thereon. In one preferred embodiment of the present invention, the bonding pad 402 is subject to a pretreatment by wet etching. An etchant used in the wet etching can be a peroxide such as hydrogen peroxide, hydrogen, or acids such as 60%-80% phosphoric acid (H₃PO₄), more than 10% nitric acid (HNO₃), more than 10% acetic acid, or the combination thereof. The surface of the bonding pad 402 becomes planar or concave after wet etching. Then, a UBM layer 408 is formed on the exposed bonding pad. A bump 410 is formed on the UBM layer 408. The bump 410 can be made of metal such as gold. Further, the bump 410 formed on either the planar surface or concave surface of the bonding pad 402 has a smooth surface.

In view of foregoing, the present invention can provide several advantages over the prior art. For example, the hillocks on the bonding pad are removed by wet etching before the bump is formed. The bonding pad, after being wet etched, has a planar or concave surface that prevents nodules from being formed on the bump in the subsequent process. Since the bump has no nodule, it can provide high reliability in processes that require high planarity of the bump.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

What is claimed is:

1. A method of forming a bump, comprising:
providing a wafer having a plurality of chips, wherein each of the chips is provided with a plurality of bonding pads thereon;
performing a wet etching using hydrogen peroxide or hydrogen fluoride;
forming an under ball metallurgy (UBM) layer on each of the bonding pads; and forming a bump on the UBM layer.

2. The method of claim 1, wherein the material used to form the bonding pad is aluminum.

3. The method of claim 1, wherein the material used to form the bump is gold.

4. The method of claim 1, further performing a dry etching process to remove a native oxide layer, if any, on the bonding pad before the UBM layer is formed.

5. The method of claim 1, wherein the bump is formed by plating.

6. A method of forming a bump, comprising:
providing a wafer having a plurality of chips, wherein each of the chips is provided with a plurality of bonding pads;
performing a wet etching using a peroxide;
forming an under ball metallurgy (UBM) layer on each of the bonding pads; and
forming a bump on the UBM layer.

7. The method of claim 6, wherein the material used to form the bonding pad is aluminum.

8. The method of claim 6, wherein the material used to form the bump is gold.

9. The method of claim 6, further performing a dry etching process to remove a native oxide layer, if any, on the bonding pad before the UBM layer is formed.

10. The method of claim 6, wherein the bump is formed by plating.

11. The method of claim 6, wherein the peroxide is hydrogen peroxide.
